(19) United States
(12) Patent Application Publication
(10) Pub. No.: US 2023/0283284 A1
(43) Pub. Date: Sep. 7, 2023

(54) ATOMIC FREQUENCY OBTAINING DEVICE AND ATOMIC CLOCK

(71) Applicant: TAMAGAWA HOLDINGS CO., LTD., Tokyo (JP)

(72) Inventor: Hitoshi Nishino, Sendaishi, Miyagi (JP)

(73) Assignee: TAMAGAWA HOLDINGS CO., LTD., Tokyo (JP)

(21) Appl. No.: 18/011,568

(22) PCT Filed: Jun. 25, 2021
(86) PCT No.: PCT/JP2021/024141

§ 371 Date: Dec. 20, 2022

(30) Foreign Application Priority Data
Jul. 10, 2020 (JP) 2020-119389

(51) Int. Cl. H03L 7/26

(52) U.S. Cl. CPC H03L 7/26

(57) ABSTRACT

[Problem] To provide an atomic frequency obtaining device which enables an improvement in mass-productivity and a reduction in size, and an atomic clock which uses the atomic frequency obtaining device.

[Solution] A laser light source 20, a vapor cell unit 30 that includes a vapor cell 31 in which atomic gas was enclosed, and a light detector 40 are provided on a circuit board 10. Light emitted from the laser light source 20 is reflected by a first reflective member 51 so that the direction in which the light travels is changed and the light passes through the vapor cell. The light passes through the vapor cell 31, and is reflected by a second reflective member 52 so that the direction in which the light travels is changed and the light travels toward the light detector 40.

### TECHNICAL FIELD

The present invention relates to an atomic frequency obtaining device and an atomic clock using the same.

### BACKGROUND ART

An atomic clock (atomic oscillator) oscillating based on energy transition of an alkali metal atom such as rubidium (Rb) or cesium (Cs) has been known as an oscillator having stable oscillation characteristics for a long period of time. Among them, in an atomic clock of a type that uses a CPT (Coherent Population Trapping) resonance effect, downsizing can be expected, so that in recent years, it is expected to be mounted on mobile communication equipment, etc.

In general, an atomic clock using a quantum interference effect such as CPT resonance includes a vapor cell in which gaseous alkali metal atoms are enclosed, a light source for resonating the alkali metal atoms in the vapor cell, and a light detector for detecting light passing through the vapor cell (for example, see Patent Document 1). As just described, in the conventional atomic clock, the light source, the vapor cell, and the light detector are linearly arranged on an arrangement substrate. Therefore, there are problems that arrangement members for aligning and arranging them on the arrangement substrate are required, the manufacturing process is complicated, and downsizing is difficult.

### CITATION LIST

### Patent Literature

Patent Literature 1: Publication of Japanese Patent Application No. 2017-219400

### SUMMARY OF INVENTION

### Technical Problem

The present invention has been made based on such problems, and an object thereof is to provide an atomic frequency obtaining device capable of improving mass productivity and reducing the size and an atomic clock using the same.

### Solution to Problem

An atomic frequency obtaining device of the present invention includes a circuit board, a laser light source arranged on the circuit board, a vapor cell unit arranged on the circuit board and having a vapor cell in which an atomic gas is enclosed, the vapor cell irradiated with light from the laser light source, a light detector arranged on the circuit board and detecting light emitted from the laser light source and passing through the vapor cell, a first reflective member reflecting the light emitted from the laser light source and changing a traveling direction of the light so as to pass through the vapor cell, and a second reflective member reflecting the light passing through the vapor cell and changing the traveling direction of the light so as to travel toward the light detector.

An atomic clock of the present invention includes the atomic frequency obtaining device of the present invention.

### Advantageous Effects of Invention

According to the present invention, the laser light source, the vapor cell unit, and the light detector are arranged on the circuit board, and the traveling direction of the light emitted from the laser light source is changed by the first reflective member and the second reflective member, so that the laser light source, the vapor cell unit, and the light detector can be directly arranged on the circuit board. Thus, the need for arrangement members for their alignments is eliminated, the manufacturing process can be simplified, the mass productivity can be improved, and the size can be reduced.

When the first reflective member and the second reflective member are configured to be arranged on a cover member and arranged on the circuit board, positioning of the first reflective member and the second reflective member can be facilitated, and the mass productivity can be improved.

When the vapor cell, a magnetic field generation means, and a heating means are configured to be sealed by a sealing member and housed in a package member, the vapor cell, the magnetic field generation means, and the heating means can be packaged and handled, and the manufacturing process can be simplified to improve the mass productivity.

### BRIEF DESCRIPTION OF DRAWINGS

FIG. 1 illustrates a configuration of an atomic frequency obtaining device according to an embodiment of the present invention.

FIG. 2 illustrates a configuration of a vapor cell unit of the atomic frequency obtaining device shown in FIG. 1 in an enlarged manner.

FIG. 3 illustrates a hyperfine structure energy level of an atom in CPT resonance.

FIG. 4 illustrates a variation of the atomic frequency obtaining device shown in FIG. 1.

### DESCRIPTION OF EMBODIMENTS

Hereinafter, an embodiment of the present invention will be described in detail with reference to the drawings.

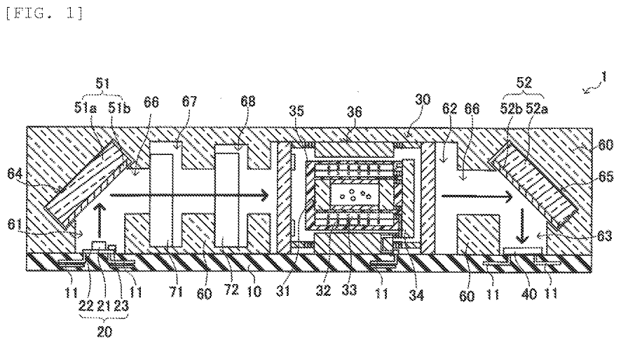

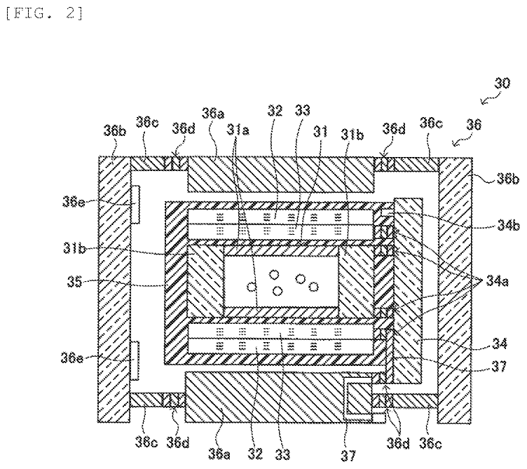

FIG. 1 illustrates a configuration of an atomic frequency obtaining device 1 according to an embodiment of the present invention. FIG. 2 illustrates a part of FIG. 1 in an enlarged manner. The atomic frequency obtaining device 1 is used as, for example, a time standard frequency generation system of a CPT-type atomic clock. The atomic frequency obtaining device 1 includes a circuit board 10, a laser light source 20, a vapor cell unit 30 having a vapor cell 31 in which an atomic gas is enclosed, and a light detector 40. The circuit board 10 is one in which conductor wiring is formed on or inside a substrate made of an insulating material. The laser light source 20, the vapor cell unit 30, and the light detector 40 are each arranged on the circuit board 10, and the laser light source 20 and the light detector 40 are connected to a control circuit (not shown) by wirings 11 formed in the circuit board 10.

The laser light source 20 is for irradiating the vapor cell 31 with a laser light. The laser light source 20 preferably has, for example, a semiconductor laser 21, and further has a temperature controller 22, such as a Peltier element, for adjusting the temperature of the semiconductor laser 21, and a temperature sensor 23, such as a thermistor, for controlling the drive of the temperature controller 22.

As the semiconductor laser 21, for example, a surface emitting laser (SEL) is preferable, and a vertical cavity surface emitting laser (VCSEL) is preferably included. The semiconductor laser 21 generates sidebands by, for example, inputting a high frequency to a bias current and modulating it, thereby emitting two lights having different wavelengths from one semiconductor laser 21, causing the two lights to pass through the vapor cell 31, thereby generating a quantum interference effect. The laser light source 21 is preferably arranged with its light emitting surface facing upward with respect to the circuit board 10 so as to emit light in a direction perpendicular to the circuit board 10, for example.

The vapor cell unit 30 has, for example, the vapor cell 31 irradiated with light from the laser light source 20, a magnetic field generation means 32 configured to apply a magnetic field to the vapor cell 31, and a heating means 33 configured to heat the vapor cell 31. The vapor cell 31, the magnetic field generation means 32, and the heating means 33 are, for example, each arranged on a vapor cell arrangement substrate 34, sealed by a sealing member 35, and housed inside a package member 36.

The vapor cell 31 is one in which an atomic gas containing an alkali metal atom such as Rb or Cs is enclosed inside. In the drawings, the alkali metal atomic gas is conceptually illustrated by small circles. The vapor cell 31 has, for example, a hollow side member 31a formed so as to surround side portions and having both ends opened, and a pair of transparent members 31b each arranged at each end of the side member 31a, and the atomic gas is enclosed in an internal space surrounded by these members. Inside the vapor cell 31, a buffer gas is preferably enclosed together with the alkali metal atom. The buffer gas preferably includes an inert gas. The inert gas is a rare gas element such as argon (Ar) or neon (Ne), or nitrogen (N₂). The side member 31a of the vapor cell 31 is, for example, made of a semiconductor or metal, and preferably made of silicon (Si) among others. This is because silicon can accommodate a micro electro mechanical system (MEMS) processing process and the alkali metal atom does not react with silicon. The transparent member 31b is, for example, made of glass, and preferably made of borosilicate glass among others.

The magnetic field generation means 32 is, for example, composed of a coil and is arranged so as to surround the periphery of the side portions of the vapor cell 31. The heating means 33 is, for example, composed of a heater wire and is arranged so as to surround the periphery of the side portions of the vapor cell 31. The vapor cell arrangement substrate 34 is, for example, made of a transparent material such as glass and is located on one end portion side of the vapor cell 31. The vapor cell 31, the magnetic field generation means 32, and the heating means 33 are, for example, bonded by a bonding layer 34a in which a gold (Au) layer, a tin (Sn) layer, and an Au layer are sequentially stacked. For example, a temperature sensor 34b, such as a thermistor, for controlling the drive of the heating means 33 is arranged on the vapor cell arrangement substrate 34 and is electrically connected to the heating means 33 by wiring (not shown) formed in the vapor cell arrangement substrate 34. The sealing member 35 is, for example, made of a light transmitting resin, and more specifically, is preferably composed of a transparent synthetic polymer material such as an epoxy resin or an acrylic resin.

The package member 36 preferably has a hollow ceramic member 36a arranged so as to surround the periphery of the side portions of the vapor cell 31 and having both ends opened, an end member 36b arranged on each end side of the ceramic member 36a, and a connection member 36c connecting the ceramic member 36a and the end member 36b. Preferably, the package member 36 is hermetically sealed and the inside thereof is evacuated. The ceramic member 36a is preferably composed of a ceramic material such as an aluminum oxide or a silicon nitride. This is because the distribution of the magnetic field and the uniformity of the temperature can be improved by surrounding the vapor cell 31, the magnetic field generation means 32, and the heating means 33 with the ceramic member 36a. The vapor cell arrangement substrate 34 is, for example, bonded to the ceramic member 36a by a bonding layer 36d in which an Au layer, an Sn layer, and an Au layer are sequentially stacked, whereby the vapor cell arrangement substrate 34 is supported by the package member 36.

The end member 36b is, for example, composed of a transparent material such as glass. For example, a getter 36e is arranged on one end member 36b. The getter 36e is for adsorbing gas remaining in a region enclosed by the package member 36 or generated in the region to form a higher vacuum. As a result, heat from the heating means 33 can be vacuum-blocked, and low power consumption can be achieved. The connection member 36c is, for example, made of silicon. The connection member 36c and the end member 36b are, for example, bonded by gold bonding or gold-tin bonding. The connection member 36c and the ceramic member 36a are, for example, bonded by the bonding layer 36d in which an Au layer, an Sn layer, and an Au layer are sequentially stacked.

The vapor cell unit 20 is, for example, arranged so that the side member 31a of the vapor cell 31 is lateral to the circuit board 10. Specifically, for example, the vapor cell unit 30 is preferably arranged so that a facing direction of the transparent members 31b of the vapor cell 31, that is, a direction in which light passes, is horizontal, specifically parallel to the circuit board 10. This is because, in a case where the light path length of the vapor cell 31 is made longer in order to increase the S/N ratio, the height of the atomic frequency obtaining device 1 is increased when the side member 31a of the vapor cell 31 is made vertical to the circuit board 10, whereas when the side member 31a of the vapor cell 31 is made horizontal to the circuit board 10, the height of the atomic frequency obtaining device 1 can be reduced and the size can be reduced. Further, for example, wiring 37 for electrically connecting the magnetic field generation means 32 and the heating means 33 to the wiring 11 of the circuit board 10 is formed in the vapor cell arrangement substrate 34 and the ceramic member 36a.

The light detector 40 detects the light emitted from the laser light source 20 and passing through the vapor cell 31, and is composed of a photodiode, for example. The light detector 40 is preferably arranged with its light receiving surface facing upward with respect to the circuit board 10 so as to receive light perpendicular to the circuit board 10.

The atomic frequency obtaining device 1 also includes a first reflective member 51 reflecting the light emitted from the laser light source 20 and changing the traveling direction of the light so as to pass through the vapor cell 31, and a second reflective member 52 reflecting the light passing through the vapor cell 31 and changing the traveling direction of the light so as to travel toward the light detector 40. As a result, the light emitted from the laser light source 20 is configured to be reflected by the first reflective member 51, pass through the vapor cell 31, be reflected by the second reflective member 52, and be received by the light detector 40. The first reflective member 51 and the second reflective member 52 have a configuration in which reflective films 51b, 52b are formed on surfaces of glass substrates 51a, 52a, for example.

The atomic frequency obtaining device 1 preferably further includes a cover member 60 arranged on the circuit board 10 and covering the laser light source 20, the vapor cell unit 30, and the light detector 40. The cover member 60 is, for example, formed with a laser light source storage space 61 for housing the laser light source 20, a vapor cell unit storage space 62 for housing the vapor cell unit 30, a light detector storage space 63 for housing the light detector 40, a first reflective member arrangement space portion 64 where the first reflective member 51 is arranged, and a second reflective member arrangement space portion 65 where the second reflective member 52 is arranged. As a result, by arranging the first reflective member 51 in the first reflective member arrangement space portion 64, arranging the second reflective member 52 in the second reflective member arrangement space portion 65, and arranging the cover member 60 on the circuit board 10, positioning of the first reflective member 51 and the second reflective member 52 can be facilitated. Further, the cover member 60 is preferably, for example, formed with a light path space 66 corresponding to a light path of the light emitted from the laser light source 20 up to the reception by the light detector 40. The cover member 60 can be composed of glass, silicon, aluminum, stainless, etc., or a composite member obtained by bonding them, for example.

The atomic frequency obtaining device 1 also may include a lens 71 and a wave plate 72 between the laser light source 20 and the vapor cell unit 30 according to need. In this case, the cover member 60 is preferably provided with a lens arrangement space portion 67 where the lens 71 is arranged, and a wave plate arrangement space portion 68 where the wave plate 72 is arranged.

The atomic frequency obtaining device 1 operates as follows, for example. The light emitted from the laser light source 20 is, for example, directed upward from the circuit board 10, is reflected by the first reflective member 51, changes the traveling direction to the direction parallel to the circuit board 10, passes through the vapor cell 31, is reflected by the second reflective member 52, changes the traveling direction to the direction toward the circuit board 10, and is received by the light detector 40. As a result, the alkali metal atom in the vapor cell 31 is excited.

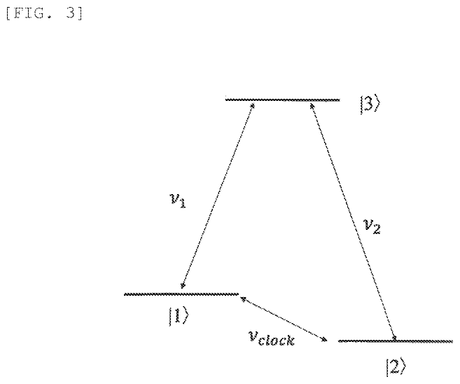

The atomic frequency obtaining device 1 uses a CPT resonance of the alkali metal atom enclosed in the vapor cell 31, and the hyperfine structure energy level of the atom in the CPT resonance is a three-level system as shown in FIG. 3, for example. In a case of transition of the D1 line of the Cs atom (6S_{1/2}→6P_{1/2}), for example, |1> level is 6S_{1/2}F4, |2> level is 6S_{1/2}F3, and |3> level is 6P_{1/2}. When the oscillation wavelength of the semiconductor laser 21 is almost coincided with a transition wavelength of 894.35 nm of the D1 line at Cs and a signal at a frequency (ν_{clock}) equal to an energy corresponding to a difference between the |1> level and the |2> level or half the frequency (ν_{clock}/2) is superimposed on the drive current of the semiconductor laser 21, the transitions of the |1> level→the |3> level and the |2> level→the |3> level do not occur, resulting in a dark resonance state. In the case of the transition of the D1 line at Cs, ν_{clock} is 9.192 GHz and ν_{clock}/2 is 4.596 GHz. At this moment, the intensity of the transmitted light by the light detector 40 becomes a peak of the maximum intensity. By controlling the frequency of the superimposed signal so that the peak becomes the maximum, a stable frequency standard is provided.

For example, the atomic frequency obtaining device 1 can be manufactured as follows. First, for example, the laser light source 20, the vapor cell unit 30, and the light detector 40 are arranged on the circuit board 10 on which a necessary circuit is formed. Next, for example, the first reflective member 51 and the second reflective member 52 are respectively arranged in the first reflective member arrangement space portion 64 and the second reflective member arrangement space portion 65 of the cover member 60, and the lens 71 is arranged in the lens arrangement space portion 67 and the wave plate 72 is arranged in the wave plate arrangement space portion 68 according to need. Subsequently, the cover member 60 is arranged on the circuit board 10. As a result, the atomic frequency obtaining device 1 is obtained.

As just described, according to the present embodiment, the laser light source 20, the vapor cell unit 30, and the light detector 40 are arranged on the circuit board 10 and the traveling direction of the light emitted from the laser light source 20 is configured to be changed by the first reflective member 51 and the second reflective member 52, so that the laser light source 20, the vapor cell unit 30, and the light detector 40 can be directly arranged on the circuit board 10. Therefore, the need for arrangement members for their alignments is eliminated, the manufacturing process can be simplified, the mass productivity can be improved, and the size can be reduced.

When the first reflective member 51 and the second reflective member 52, and the lens 71 and the wave plate 72 as needed are configured to be arranged on the cover member 60 and arranged on the circuit board 10, positioning of the first reflective member 51, the second reflective member 52, the lens 71, and the wave plate 72 can be facilitated, and the cover member 60 on which these optical components are arranged is pressed against and arranged on the vapor cell unit 30 arranged on the circuit board 10, whereby a high degree of alignment is not required and the mass productivity can be improved.

When the vapor cell 31, the magnetic field generation means 32, and the heating means 33 are configured to be sealed by the sealing member 35 and housed in the package member 36, the vapor cell 31, the magnetic field generation means 32, and the heating means 33 can be packaged and handled, and the manufacturing process can be simplified to improve the mass productivity.

The present invention has been described above with reference to the embodiment. However, the present invention is not limited to the foregoing embodiment and variations, and various modifications can be made. For example, although each component has been specifically described in the above embodiment, all the components do not have to be included and other components may be included.

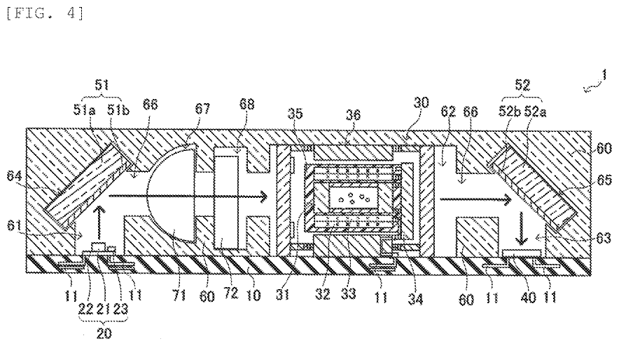

The specific configuration of each component is an example and may be different. For example, as shown in FIG. 4, the lens 71 may be composed of a hemispherical lens. Further, for example, a reading circuit element, a signal amplifying circuit element, a temperature control circuit element for the vapor cell 31, or a magnetic field control circuit element may be formed on the circuit board 10. In addition, a part or all of a detector circuit, a phase locked loop (PLL), an oscillator, a modulation circuit, etc., for operation of the atomic clock may be formed on the circuit board 10.

### REFERENCE SIGNS LIST

1 . . . Atomic frequency obtaining device, 10 . . . Circuit board, 11 . . . Wiring, 20 . . . Laser light source, 21 . . . Semiconductor laser, 22 . . . Temperature controller, 23 . . . Temperature sensor, 30 . . . Vapor cell unit, 31 . . . Vapor cell, 31a . . . Side member, 31b . . . Transparent member, 32 . . . Magnetic field generation means, 33 . . . Heating means, 34 . . . Vapor cell arrangement substrate, 34a . . . Bonding layer, 34b . . . Temperature sensor, 35 . . . Sealing member, 36 . . . Package member, 36a . . . Ceramic member, 36b . . . End member, 36c . . . Connection member, 36d . . . Bonding layer, 36e . . . Getter, 37 . . . Wiring, 40 . . . Light detector, 51 . . . First reflective member, 51a . . . Glass substrate, 51b . . . Reflective film, 52 . . . Second reflective member, 52a . . . Glass substrate, 52b . . . Reflective film, 60 . . . Cover member, 61 . . . Laser light source storage space, 62 . . . Vapor cell unit storage space, 63 . . . Light detector storage space, 64 . . . First reflective member arrangement space portion, 65 . . . Second reflective member arrangement space portion, 66 . . . Light path space, 67 . . . Lens arrangement space portion, 68 . . . Wave plate arrangement space portion, 71 . . . Lens, 72 . . . Wave plate

1. An atomic frequency obtaining device comprising:
a circuit board;
a laser light source arranged on the circuit board;
a vapor cell unit arranged on the circuit board and having a vapor cell in which an atomic gas is enclosed, the vapor cell irradiated with light from the laser light source;
a light detector arranged on the circuit board and detecting light emitted from the laser light source and passing through the vapor cell;
a first reflective member reflecting the light emitted from the laser light source and changing a traveling direction of the light so as to pass through the vapor cell; and
a second reflective member reflecting the light passing through the vapor cell and changing the traveling direction of the light so as to travel toward the light detector.

2. The atomic frequency obtaining device according to claim 1, further comprising a cover member arranged on the circuit board and formed with a laser light source storage space for housing the laser light source, a vapor cell unit storage space for housing the vapor cell unit, a light detector storage space for housing the light detector, a first reflective member arrangement space portion where the first reflective member is arranged, and a second reflective member arrangement space portion where the second reflective member is arranged.

3. The atomic frequency obtaining device according to claim 1, wherein the vapor cell unit has:
the vapor cell;
a magnetic field generation means configured to apply a magnetic field to the vapor cell;
a heating means configured to heat the vapor cell;
a vapor cell arrangement substrate on which the vapor cell, the magnetic field generation means, and the heating means are arranged;
a sealing member sealing the vapor cell, the magnetic field generation means, and the heating means; and
a package member arranged on the vapor cell arrangement substrate and housing the vapor cell, the magnetic field generation means, and the heat means sealed by the sealing member therein.

4. An atomic clock comprising the atomic frequency obtaining device according to claim 1.
